(19) United States
(12) Patent Application Publication
(10) Pub. No.: US 2024/0322776 A1
(43) Pub. Date: Sep. 26, 2024

(54) PHASE INVARIANT VARIABLE GAIN AMPLIFIER FOR A WIRELESS SYSTEM

(71) Applicant: BDCM A2 LLC, Dover, DE (US)

(72) Inventors: Ahmet Hakan COSKUN, Burlington, MA (US); Wei-Min KUO, Redondo Beach, CA (US)

(21) Appl. No.: 18/614,454

(22) Filed: Mar. 22, 2024

Related U.S. Application Data
(60) Provisional application No. 63/453,973, filed on Mar. 22, 2023.

(51) Int. Cl. H03G 3/30; H01Q 3/38; H03F 3/19

(52) U.S. Cl. CPC H03G 3/3036; H01Q 3/38; H03F 3/19; H03G 2201/103; H03G 2201/307

(57) ABSTRACT

A variable gain amplifier is disclosed having parallel sets of transistors and control for bias voltages, wherein the average of bias voltage values is strategically controlled to reduce phase variance. For example, a variable gain amplifier may include a first set of transistors coupled to a first bias voltage, a second set of transistors coupled to a second bias voltage, where the second set of transistors is coupled in parallel with the first set of transistors, and a control module adapted to control the first and second bias voltages, the control module adapted to reduce the gain of the first set of transistors while increasing the gain of the second set of transistors.

### CROSS-REFERENCE TO RELATED APPLICATIONS

This application claims the benefit of and priority to U.S. Provisional Application No. 63/453,973 filed on Mar. 22, 2023, the disclosure of which is incorporated herein by reference in its entirety.

### TECHNICAL FIELD

The present disclosure relates to variable gain amplifiers, and more specifically to phase control of a circuit having parallel sets of transistors.

### BACKGROUND

Autonomous driving and Advanced-Driver Assistance Systems (“ADAS”) automate, adapt and enhance vehicles for safety and better driving. The requirements for object and image detection are critical and specify the time required to capture data, process it and turn it into action. All of the aforementioned tasks are to be performed while ensuring accuracy, consistency and cost optimization.

The capability of a system is often defined by the ability of a sensor, such as a radar system, to detect and classify objects in a field of view. For a radar device as an example, the ability to form and steer the electromagnetic beam determines the range and angular resolution of the device.

Variable Gain Amplifier (VGA) is a key component of wireless transmit and receive systems. The system controls the signal level of radio frequency (RF) signals by adjusting the bias voltage of the VGA. The signal propagates through frontend of the system and radiates from antenna elements. Signals processed by RF building blocks are subject to a time delay which is dictated by the phase of the RF block. The phase of a VGA inherently varies with the gain setting due to the transistor characteristics. This behavior causes non-ideal operation of the wireless system.

### BRIEF DESCRIPTION OF THE DRAWINGS

The present application may be more fully appreciated in connection with the following detailed description taken in conjunction with the accompanying drawings, which are not drawn to scale, in which like reference characters refer to like parts throughout, and in which:

FIG. 1 illustrates a block diagram of a hybrid beam steering radar system and its functions, in accordance with one or more implementations of the subject technology;

FIG. 2 illustrates a transmit portion of a hybrid beam steering radar system, in accordance with one or more implementations of the subject technology;

FIG. 3 illustrates an antenna system having beamforming capability with a RFIC beamformer for controlling transmission signals radiating from antenna array;

FIG. 4 illustrates receive portion of a hybrid beam steering radar system, in accordance with one or more implementations of the subject technology; and

FIG. 5 depicts an illustrative flowchart for an example method for phase control in a circuit having parallel sets of transistors.

### DETAILED DESCRIPTION

The present disclosure generally relates to systems and methods for phase invariant variable gain amplification, such as in a wireless system. A variable gain amplifier (VGA) may be made up of one or multiple stages where the VGA design is intended to improve performance and range while reducing distortion over a large bandwidth providing a flat signal level profile.

In a phase controlled integrated circuit, random or unintended phase changes result in operation. The phase shift in a variable gain amplifier (VGA) has a direct relation to the amplification of signals. These amplitude changes impact beamsteering and the antenna directivity. Some systems address this issue by calibrating the system and manipulating the phase shift control values using a look up table (LUT). It may be desirable to eliminate this variance in the phase shifter control circuit. The examples described herein provide methods for phase invariant control to solve the problems of prior art systems.

In an example application described herein the VGA is part of a radar system for advance driver assist systems (ADAS) or vehicles having autonomous capability and therefore a radar system is provided in this introduction. For object detection in a radar system, for example, signals are transmitted using a modulation enabling acquisition of information from the analog signals directly. One such system employs Frequency Modulation Continuous Waveform (“FMCW”) techniques to capture range and velocity directly from the received signals. At each angle of arrival (AoA), the generated beam has a bandwidth or beam width, generally measured at the half power gain, or −3 dB. The angular resolution of the radar system is thus limited by this beam width as multiple objects therein are not easily distinguished.

It is critical in such a radar system to refine angular resolution for object detection at high speed so the radar system is able to identify and resolve multiple objects. The radar disclosed herein is a beam steering radar capable of generating narrow, directed beams that may be steered to any angle (i.e., from 0° to 360°) across a Field of View (“FoV”) to detect objects. These radar solutions and examples provided herein illustrate 2-D angles of transmission, enabling object detection in two planes of the FoV. The beams are generated and steered in the analog domain, while processing of received radar signals for object identification is performed with advanced signal processing and machine learning techniques. In various implementations, objects are detected in a received radar signal with the help of one or more guard band antennas to effectively resolve multiple objects inside a main beam with a high degree of accuracy and angular resolution. Radar angular resolution, as generally described herein, is the minimum distance between two equally large objects at the same range which the radar is able to distinguish and separate from each other.

It is to be understood that for transmission of a signal, propagation flows from a signal source through a phase shifter which adjusts the phase of one or more radiating elements in an antenna array to direct a radiation beam. The waveform of the transmitted signal may be described as:

$$s ( t ) = A \cdot sin [ 2 π f ( t ) \cdot t + φ ( t ) ]$$

wherein A is the amplitude modulation, a variation of the amplitude as a function of time, t, f is the frequency of the signal, and φ is the phase of the signal. A variety of applications and configurations are possible. In a radar system, specifically, a receive antenna responds to reflections or echoes of signals from objects in the environment. The received signals are compared to the transmitted signal to identify a range and velocity of the objects. For objects at the same range and velocity, the received signals may create a false impression and indicate a single object at an intermediate location.

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology is not limited to the specific details set forth herein and may be practiced using one or more implementations. In one or more instances, structures and components are shown in block diagram form in order to avoid obscuring the concepts of the subject technology. In other instances, well-known methods and structures may not be described in detail to avoid unnecessarily obscuring the description of the examples. Also, the examples may be used in combination with each other.

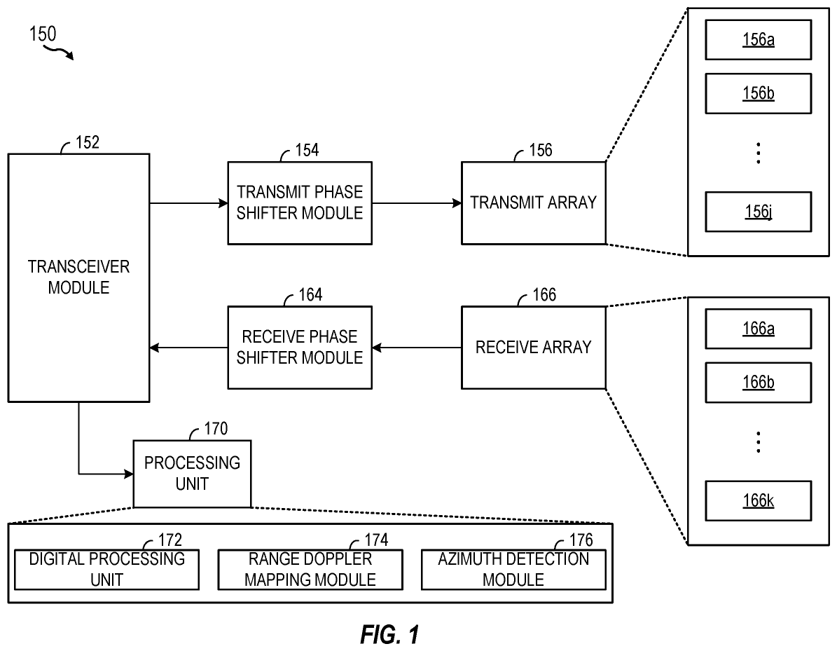

FIG. 1 illustrates a hybrid beam steering radar system 150 configured to generate scanning beams and includes transceiver module 152 (also referred to herein as transceiver 152) in the transmit path and the receive path. As illustrated in FIG. 1, the transmit path includes a path from the transceiver module 152 to transmit phase shifter module 154 and to transmit array 156. Similarly, the receive path includes a path from a receive array 166 to receive phase shifter module 164 and to transceiver module 152.

In various implementations, the transceiver module 152 includes a waveform generator, power amplifier and other components (not shown) to facilitate signal transmission. The transceiver module 152 has the ability to support both transmit operation and receive operation. The transceiver module 152 includes filters, low noise amplifiers and other components (not shown) to facilitate receive operations. During transmit operation, transceiver module 152 generates modulated waveforms, such as by frequency modulated continuous waveform (FMCW), for transmission. The transmit array 156 is the source transmission of a waveform in the FoV, which is a fan beam in azimuth and a narrow beam in elevation. The waveform is a repeating frequency signal of electromagnetic waves. It is steered by phase shifting the components of the transmit signal, which then propagates over the air from the antenna array 156 within a FoV. The radar system 150 is designed to detect objects within the FoV and distinguish objects of interest, targets, from noise from other objects. This is the case where the radar system 150 detects a vehicle but ignores a small bird. When the transmission signal contacts a target in the FoV, energy reflects, sometimes referred to as backscatter, in the direction of the radar system 150 and excites the receive antenna array 166. The transmit antenna array 156 is composed of one or more arrays of radiating elements, 156a, 156b, through 156j. The transmit beam interacts with a target and reflects at least a portion of the incident waveform energy from the transmit array 156 back to the receive array 166. The receive array 166 is composed of one or more arrays of radiating elements 166a, 166b, through 166k.

In accordance with various implementations, radar system 150 is configured to apply phase shift(s) to one or more paths propagating signals to one or more radiating elements of the transmit array 156 to generate a transmission beam; the transmission beam is a composite of the individual beams from the radiating elements. The applied phase shift(s) are coordinated with phase shift(s) applied to receive signals from receive array 166. The receive array 166 collects energy reflected from the target(s) from a surrounding or a vicinity. The transmission beam is compared to the received signals to determine range, angle of arrival and potential other information on detection of a target, as the target acts to reflect or return the transmission signal. The transmission beam is a broad fan beam in one direction and is incremented in a second direction. In the present examples, the fan beam is in the azimuth direction, while the beam is incremented in elevation.

The transmit path is from transceiver module 152 to transmit phase shifter module 154 and finally to transmit array 156. Transceiver module 152 is coupled to transmit phase shifter module 154 having one or more phase shifting elements applied to the transmission signal so as to shift the waveform transmitted at individual radiating elements of the transmit array 156. The phase shift is introduced for beamforming and beam steering. In this way, the transmit array 156 generates a fan beam in the azimuth and steers the beam in elevation. Transmit array 156 includes one or more individual arrays of elements, such as in columns or rows. Each individual array 156a, 156b, through 156j, corresponds to a specific area in the azimuth and may be used to identify a target location as discussed herein.

The receive path is from receive array 166 to receive phase shifter module 164, transceiver module 152 and finally to processing unit 170. Transceiver module 152 is coupled to receive phase shifter module 154 having one or more phase shifting elements applied to the received signal(s) so as to correspond to the transmitted waveform. This comparison provides information related to Doppler shift, phase shift and frequency shift in the received signal to determine range and angle of arrival information. This information is extracted in the transceiver module 152 and forwarded to processing unit 170 for further identification of the location of a detected target.

In some embodiments, transmissions forming the scanning beams over a FoV involves transmitting a fan beam at each of a set of incremented elevation angles. The specific configuration and operation of radar system 150 is provided for clarity of understanding and it is understood that the elevation and azimuth may be reversed, wherein a fan beam is transmitted in elevation and a narrow beam in azimuth.

Continuing with the transceiver module 152 and transmit phase shifter module 154 set the elevation angle, wherein a target within the FoV at a given elevation angle may be anywhere within the azimuth direction. To determine the azimuth direction, the processing unit 170 correlates signals received at the radiating elements of the receive array 166. In some embodiments, this employs a super resolution method enabling the radar system 150 to distinguish between multiple targets in close proximity.

The radar system 150 increments the elevation angle of transmissions so that the fan beam in the azimuth is transmitted at various elevations. In some embodiments, the radar system 150 increments the radar beam in successive elevations, e.g., elevation angles. In some embodiments, the radar system 150 covers a span of elevation angles as a function of radar performance, desired FoV or other criteria, wherein the elevation angles are not necessarily applied in order, e.g., sequentially order. In some embodiments, the elevation angles may be applied in a predetermined order, e.g., based on input from other sensors, e.g., camera or LiDAR.

The processing unit 170 operates on detection of a target or object in the FoV of the radar, and determines a range to the target, the Doppler shift in return signal, and other parameters. The elevation angle provides a vertical location of the target, while modules within processing unit 170 determine a horizontal component of the target location. The processing unit 170 includes a digital processing unit 172, a range Doppler mapping (RDM) module 174 and an azimuth detection module 176. The digital signal processing (DSP) unit 172 is configured to translate the analog signals received from the transceiver module 152 into digital signals for computation of target analytics. The transceiver module 152 provides return signals in analog form, after phase shift adjustment, organized for correlation and analysis of signals received at a given elevation across the azimuth FoV. The digital processing unit 172 takes this information converts the analog to digital signals. The digital information is provided to RDM module 174, which compares the received signal to transmitted signal to determine range, change in phase, change in frequency, velocity, angle of arrival and so forth. The azimuth detection module 176 is configured to evaluate the signals received across the fan beam in the azimuth so as to apply a super resolution method to identify azimuth location. Note that the monopulse channels are not limited to the number of subarrays of the examples provided herein, and more may be implemented as a function of the number of data channels available. In some embodiments, there are equal number of monopulse channels on the top and the bottom of the receive channel.

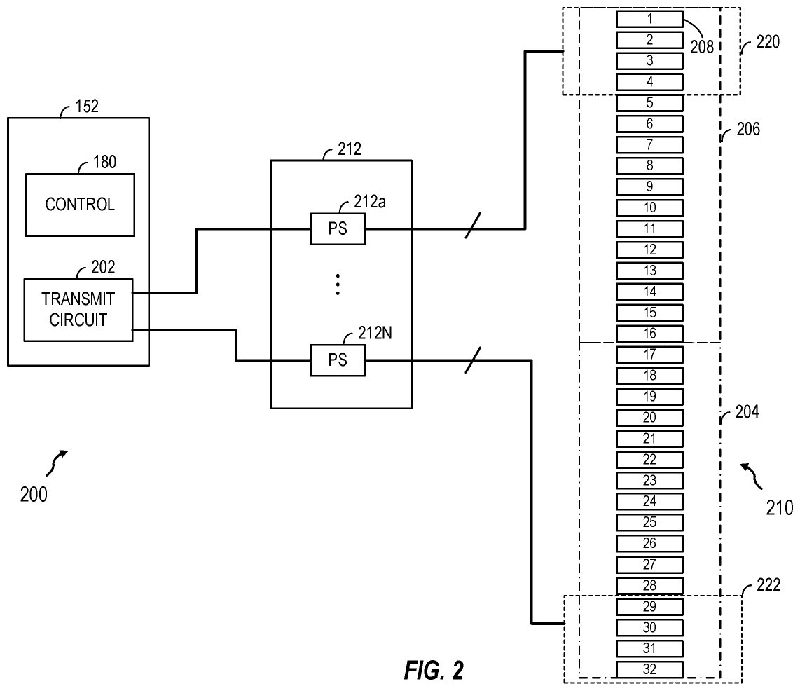

FIG. 2 illustrates a transmit portion 200 of radar system 150 as in FIG. 1 and for generating scanning beams as in FIG. 1. Portions of the transceiver module 152 illustrated in this perspective include a control unit 180, such as a microcontroller or application specific integrated circuit (ASIC) and transmit circuitry 202 as described hereinabove. The control unit 180 may include one or more memories with process-executable instructions, and one or more processors configured to execute the process-executable instructions for performing one or more of the methods depicted and described herein. The transceiver module 152 is coupled to millimeter integrated circuit (MMIC) 212, which is a radio frequency integrated circuit (RFIC), having at least one phase shift circuit, such as PS 212ₐ, and may include multiple phase shift circuits 212ₐ through 212_{N}. The transmit antenna array 210 in this embodiment includes multiple portions or channels 208, which are grouped into multiple sets 206, 204. Within set 206, several channels are grouped together, such as group 220, wherein each group is then coupled to a phase shift circuit. As illustrated, group 220 is coupled to phase shifter 212ₐ, and group 222 is coupled to phase shifter 212_{N}. There may be a variety of configurations which are implemented depending on the ports and capabilities of the phase shifters, MMIC 212, and transmit antenna array 210.

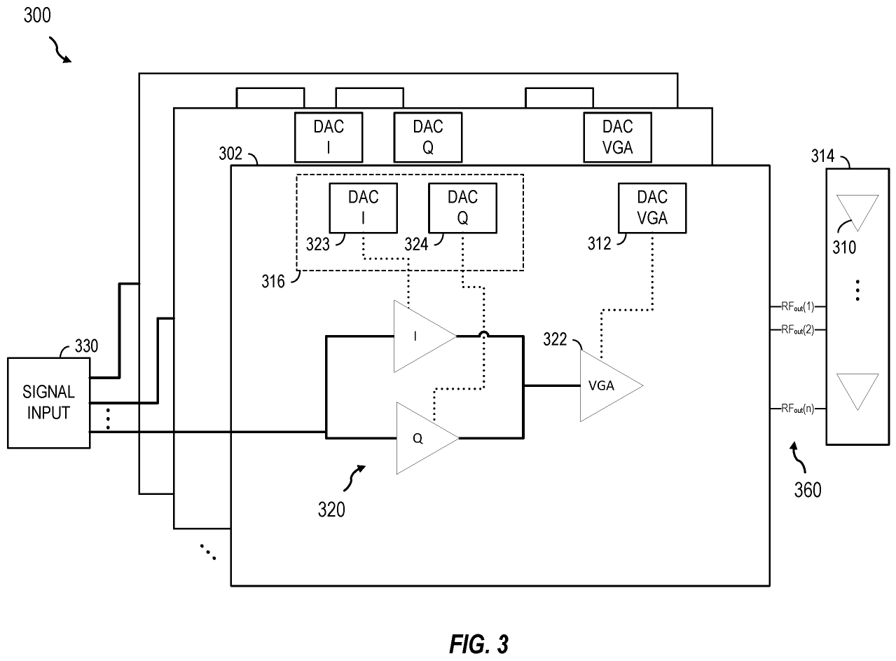

FIG. 3 illustrates an antenna system 300 having beamforming capability with RFIC beamformer 302, having phase shifter 320, VGA 322, for controlling transmission signals radiating from antenna array 314. The RFIC beamformer 302 includes multiple transmission channels 330 coupled to antenna elements 310 within antenna array 314, wherein each transmission path includes a RFIC beamformer, such as RFIC beamformer 302. In this example, the RFIC beamformer 302 is illustrated in a schematic format with a simplified transmit (Tx) module for purposes of explanation and clarity of understanding; however, an antenna system may include receive (Rx) or a combination of both (Tx/Rx). Each channel of an antenna system is defined by a transmission path from a transceiver (not shown) to an antenna element, such as antenna element 310.

Along each transmission path 330 corresponding to a channel are phase shift components, which in this example are analog components, and a variable gain amplifier (VGA). The output of each channel is a signal RFₒᵤₜ that is input to an antenna element, such as signal RFₒᵤₜ₍ₙ₎ to antenna element 310. There is one input to each channel. In some embodiments, the <I,Q> signals are defined by the DAC module 316, resulting in 256 states or data points for DAC 323 and 256 states for DAC 324. The <I,Q> performance results in (256*256) which is 65,536 states. The VGA module 322 is actuated by voltage control realized by an 8-bit DAC 312.

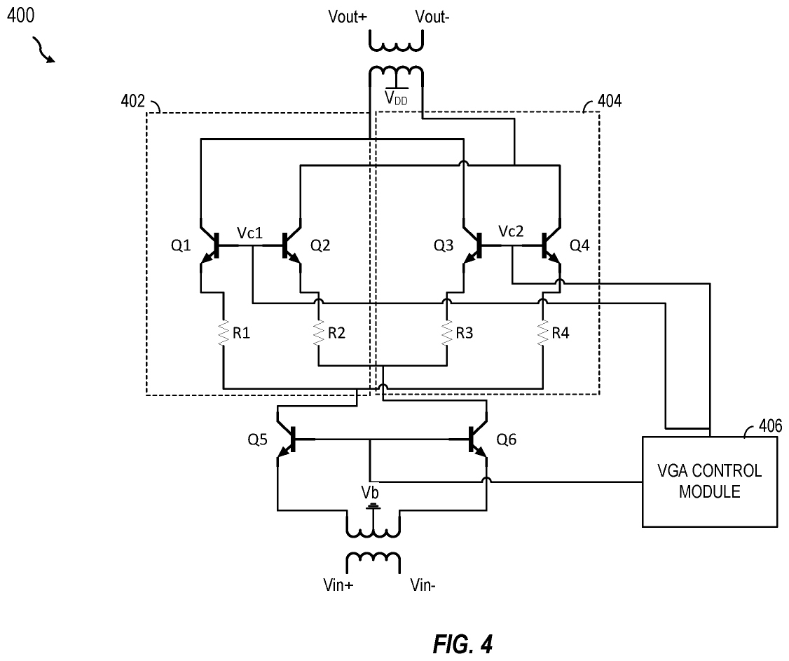

As in the systems described herein, a phase shifter module includes a variable gain amplifier as illustrated in FIG. 4. Variable Gain Amplifier (VGA) is a key component of wireless transmit and receive systems. The system controls the signal level of radio frequency (RF) signals by adjusting the bias voltage of the VGA. The signal propagates through a frontend of the system and radiates from antenna elements. Signals processed by RF building blocks are subject to a time delay which is dictated by the phase of the RF block. The phase of a VGA inherently varies with the gain setting due to the transistor characteristics. This behavior causes non-ideal operation of the wireless system.

Some multi-path wireless systems, such as a beamforming transmitter/receiver, require each path of a VGA to have independent gain control while maintaining a constant phase across all channels. Using a phase variant VGA in this scenario would require calibrating the entire system across different gain settings to counterbalance the phase offsets created by the VGA. This calibration is a time-consuming process requiring adjustment of a phase shifter, which allows controlling the beam direction, for every gain step. A phase invariant VGA eliminates this calibration process, therefore streamlining the production of a beamforming system.

FIG. 4 is a schematic block diagram of a differential current-steering VGA 400 having bipolar transistors Q1 and Q2 forming portion 402 coupled to bipolar transistors Q3 and Q4, forming portion 404. The supply voltage VDD is applied to each of the transistors Q1, Q2, Q3, and Q4. A bias voltage Vc1 is applied to transistors Q1 and Q2; a bias voltage Vc2 is applied to transistors Q3 and Q4. Transistors Q1 and Q2 are coupled to resistors R1 and R2, respectively. Transistors Q3 and Q4 are coupled to resistors R3 and R4, respectively. The circuit includes bipolar transistors Q5 and Q6 having a bias voltage Vb. A VGA controller module 406 is coupled to Vc1, Vc2 and Vb and adapted for controlling each.

In contrast to prior art and conventional VGA circuits, the operating principle of VGA 400 is to cancel out the signal by summing each side of the differential pair 402, 404, which are out of phase with each other. For maximum gain, transistors Q1 and Q2 are fully turned on while transistors Q3 and Q4 are turned off. As illustrated, Vc1 provides a bias voltage to portion 402 and Vc2 provides a bias voltage to portion 404. In this way, portion 402 is turned on and off via bias control Vc1 and pair 404 is turned on and off by bias control Vc2. In operation, Vc1 lowers the gain of portion 402 gradually while Vc2 increases the gain of portion 404. When Vc1=Vc2, the signal is completely attenuated.

The total capacitance-to-ground created by transistors Q1, Q2, Q3, and Q4 is not constant as the current is steered from one pair of transistors to another, such as portion 402 and 404. This creates a phase variance of VGA 400. Due to the nonlinear nature of transistors, the total capacitance is different for the mid gain state compared to the low and high gain states. The use of resistors R1, R1, R3 and R4 act as a feedback mechanism to reduce the phase variance. The resistor values may be quite high depending on other design parameters, and such large value resistance would limit the high-end gain.

To avoid the use of the high resistance, the phase invariance (of the VGA 400) is achieved by counteracting the change in capacitance by adjusting the contribution (of capacitance) from the bottom transistor pair, Q5 and Q6. In some embodiments VGA 400 adjusts the voltage of the node between upper and lower transistors which does not significantly impact other operational parameters. This may be implemented by manipulation of the average of control voltages, Vc1 and Vc2. By having a non-constant average of the two voltages, given by (Vc1+Vc2)/2, the capacitance contribution from the bottom pair, Q5 and Q6, is adjusted to compensate for the changes in capacitance generated by transistors Q1, Q2, Q3, and Q4, as the overall gain of the VGA 400 is altered. This makes operation of VGA 400 phase invariant. This fundamental concept is applicable to a broad range of process technologies and nodes that offer bipolar transistors.

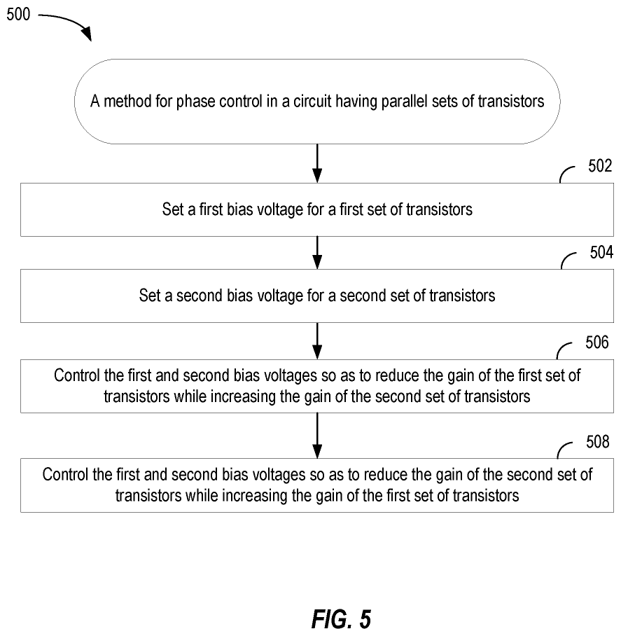

FIG. 5 depicts an example method for phase control in a circuit having parallel sets of transistors.

In this example, method 500 begins at step 502 with setting a first bias voltage for a first set of transistors. For example, the first bias voltage may be bias voltage Vc1 as depicted and described with reference to FIG. 4. For example, the first set of transistors may be transistors Q1 and Q2 as depicted and described with reference to FIG. 4. In another example, the first bias voltage may be bias voltage Vc2 or other bias voltage Vb as depicted and described with reference to FIG. 4. For example, the first set of transistors may be transistors Q3 and Q4 or alternatively transistors Q5 and Q6 as depicted and described with reference to FIG. 4. The first bias voltage may be controlled by the VGA controller module 406.

Method 500 proceeds to at step 504 with setting a second bias voltage for a second set of transistors. For example, the second bias voltage may be bias voltage Vc2 as depicted and described with reference to FIG. 4. For example, the second set of transistors may be transistors Q3 and Q4 as depicted and described with reference to FIG. 4. In another example, the second bias voltage may be bias voltage Vc2 or other bias voltage Vb as depicted and described with reference to FIG. 4. For example, the first set of transistors may be transistors Q1 and Q2 or alternatively transistors Q5 and Q6 as depicted and described with reference to FIG. 4. The first bias voltage may be controlled by the VGA controller module 406.

Method 500 proceeds to at step 506 with controlling the first and second bias voltages so as to reduce the gain of the first set of transistors while increasing the gain of the second set of transistors. For example, as illustrated in FIG. 4, Vc1 provides a bias voltage to portion 402 and Vc2 provides a bias voltage to portion 404. In this way, portion 402 is turned on and off via bias control Vc1 and pair 404 is turned on and off by bias control Vc2. In operation, Vc1 lowers the gain of portion 402 gradually while Vc2 increases the gain of portion 404. When Vc1=Vc2, the signal is completely attenuated.

In some embodiments, method 500 proceeds to at step 508 with controlling the first and second bias voltages so as to reduce the gain of the second set of transistors while increasing the gain of the first set of transistors.

As discussed herein, the transistors may be bipolar transistors. Additionally, the circuit may be adapted for beamsteering an antenna as depicted and described herein.

Note that FIG. 5 is just one example of a method, and other methods including fewer, additional, or alternative steps are possible consistent with this disclosure.

### EXAMPLE CLAUSES

Implementation examples are described in the following numbered clauses:

Clause 1: A variable gain amplifier, comprising: a first set of transistors coupled to a first bias voltage; a second set of transistors coupled to a second bias voltage, wherein the second set of transistors is coupled in parallel with the first set of transistors; and a control module adapted to control the first and second bias voltages, the control module adapted to reduce the gain of the first set of transistors while increasing the gain of the second set of transistors.

Clause 2: The variable gain amplifier of Clause 1, wherein at least one of the first set of transistors or the second set of transistors are bipolar transistors.

Clause 3: The variable gain amplifier of Clause 2, wherein when the first and second bias voltages are equal, an output signal is completely attenuated.

Clause 4: The variable gain amplifier of Clause 2, wherein first set of transistors is coupled to a first resistance element and the second set of transistors is coupled to a second resistance element.

Clause 5: The variable gain amplifier of Clause 4, wherein the first and second resistance elements act as feedback to adjust the output signal due to capacitance variations as the control module controls the first and second biases.

Clause 6: The variable gain amplifier of Clause 4, wherein the first and second set of resistors are coupled to a third set of transistors.

Clause 7: The variable gain amplifier of any one of Clauses 1-6, wherein the control module is further adapted to reduce the gain of the second set of transistors while increasing the gain of the first set of transistors.

Clause 8: A method for phase control in a circuit having parallel sets of transistors, comprising: setting a first bias voltage for a first set of transistors; setting a second bias voltage for a second set of transistors; controlling the first and second bias voltages so as to reduce the gain of the first set of transistors while increasing the gain of the second set of transistors

Clause 9: The method of Clause 8, further comprising controlling the first and second bias voltages so as to reduce the gain of the second set of transistors while increasing the gain of the first set of transistors.

Clause 10: The method of Clause 8, wherein at least one of the first set of transistors or the second set of transistors are bipolar transistors.

Clause 11: The method of Clause 10, wherein the circuit is adapted for beamsteering an antenna.

Clause 12: A beamforming circuit, comprising: a phase shifter module, comprising: a first set of transistors coupled to a first bias voltage; a second set of transistors coupled to a second bias voltage, wherein the second set of transistors is coupled in parallel with the first set of transistors; and a control module adapted to control the first and second bias voltages, the control module adapted to reduce the gain of the first set of transistors while increasing the gain of the second set of transistors; and an antenna array coupled to the phase shifter module.

It is appreciated that the previous description of the disclosed examples is provided to enable any person skilled in the art to make or use the present disclosure. Various configurations and transistor scenarios may be improved by the methods and circuits described herein. Various modifications to these examples will be readily apparent to those skilled in the art, and the generic principles defined herein may be applied to other examples without departing from the spirit or scope of the disclosure. Thus, the present disclosure is not intended to be limited to the examples shown herein but is to be accorded the widest scope consistent with the principles and novel features disclosed herein.

### ADDITIONAL CONSIDERATIONS

The terminology used herein is for the purpose of describing particular aspects only and is not intended to be limiting. As used herein, the singular forms “a,” “an,” and “the” are intended to include the plural forms, including “at least one,” unless the content clearly indicates otherwise. “Or” means “and/or.” As used herein, the term “and/of” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

It will be apparent to those skilled in the art that various modifications and variations can be made in the present disclosure without departing from the spirit or scope of the disclosure. Thus, it is intended that the present disclosure cover the modifications and variations of this disclosure provided they come within the scope of the appended claims and their equivalents.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described exemplary embodiments, but should be defined only in accordance with the following claims and their equivalents.

What is claimed is:

1. A variable gain amplifier, comprising:
a first set of transistors coupled to a first bias voltage;
a second set of transistors coupled to a second bias voltage, wherein the second set of transistors is coupled in parallel with the first set of transistors; and
a control module adapted to control the first and second bias voltages, the control module adapted to reduce a gain of the first set of transistors while increasing a gain of the second set of transistors.

2. The variable gain amplifier of claim 1, wherein at least one of the first set of transistors or the second set of transistors are bipolar transistors.

3. The variable gain amplifier of claim 2, wherein when the first and second bias voltages are equal, an output signal is completely attenuated.

4. The variable gain amplifier of claim 2, wherein the first set of transistors is coupled to a first resistance element and the second set of transistors is coupled to a second resistance element.

5. The variable gain amplifier of claim 4, wherein the first and second resistance elements act as feedback to adjust an output signal due to capacitance variations as the control module controls the first and second biases.

6. The variable gain amplifier of claim 4, wherein the first and second set of resistors are coupled to a third set of transistors.

7. The variable gain amplifier of claim 1, wherein the control module is further adapted to reduce the gain of the second set of transistors while increasing the gain of the first set of transistors.

8. A method for phase control in a circuit having parallel sets of transistors, comprising:
setting a first bias voltage for a first set of transistors;
setting a second bias voltage for a second set of transistors; and
controlling the first and second bias voltages so as to reduce a gain of the first set of transistors while increasing a gain of the second set of transistors.

9. The method of claim 8, further comprising controlling the first and second bias voltages so as to reduce the gain of the second set of transistors while increasing the gain of the first set of transistors.

10. The method of claim 8, wherein at least one of the first set of transistors or the second set of transistors are bipolar transistors.

11. The method of claim 10, wherein the circuit is adapted for beamsteering an antenna.

12. A beamforming circuit, comprising:
a phase shifter module, comprising:
a first set of transistors coupled to a first bias voltage;
a second set of transistors coupled to a second bias voltage, wherein the second set of transistors is coupled in parallel with the first set of transistors; and
a control module adapted to control the first and second bias voltages, the control module adapted to reduce a gain of the first set of transistors while increasing a gain of the second set of transistors; and
an antenna array coupled to the phase shifter module.
